(19) United States
(12) Patent Application Publication
(10) Pub. No.: US 2025/0343557 A1
(43) Pub. Date: Nov. 6, 2025

(54) TIMING CONTROL FOR CONVERSION CIRCUITRY

(71) Applicant: TEXAS INSTRUMENTS INCORPORATED, DALLAS, TX (US)

(72) Inventors: Nitin AGARWAL, BANGALORE (IN); Varun UPADHYAYA, NEW DELHI (IN); Neeraj SHRIVASTAVA, BANGALORE (IN)

(21) Appl. No.: 18/820,136

(22) Filed: Aug. 29, 2024

(30) Foreign Application Priority Data
May 6, 2024 (IN) 202441035688

(51) Int. Cl. H03M 1/12

(52) U.S. Cl. CPC H03M 1/121

(57) ABSTRACT

In a described example, a circuit includes a regulator circuit having a regulator output. A comparator circuit includes a voltage input, a clock input, and a signal output, in which the voltage input is coupled to the regulator output. A clock generator circuit has a second voltage input and the clock generator includes a programmable delay circuit, the programmable delay circuit having a signal input, a control input, and a clock output, in which the second voltage input is coupled to the regulator output, the signal input is coupled to the signal output, the clock output is coupled to the clock input. A controller includes a control output coupled to the control input.

### RELATED APPLICATION

This application claims priority from Indian Provisional Patent Application Ser. No. 202441035688, filed May 6, 2024, which is incorporated herein by reference in its entirety.

### TECHNICAL FIELD

This description relates a circuit to control timing for conversion circuitry, such as analog-to-digital converters.

### BACKGROUND

Analog-to-digital converters (ADCs) are used in a variety of applications to convert analog signals into digital signals. In high-speed ADCs, a ping-pong scheme can be used to reduce the overall latency. The ping-pong scheme uses two signal sampling capacitors, in which one capacitor is used for sampling while the other capacitor is being used for data conversion. An on-chip LDO can be configured to provide a supply voltage across an internal decoupling capacitor (DECAP). The on-chip LDO supply is loaded during ADC operation by multiple sources, which can include comparator switching, sampling capacitor switching, and ADC clock generation circuits. Due to this supply loading, the output voltage provided by the on-chip LDO includes a ripple.

### SUMMARY

One described example relates to a circuit that includes a regulator circuit having a regulator output. A comparator circuit includes a voltage input, a clock input, and a signal output, in which the voltage input is coupled to the regulator output. A clock generator circuit has a second voltage input and the clock generator includes a programmable delay circuit, the programmable delay circuit having a signal input, a control input, and a clock output, in which the second voltage input is coupled to the regulator output, the signal input is coupled to the signal output, the clock output is coupled to the clock input. A controller includes a control output coupled to the control input.

Another example circuit includes a regulator circuit configured to provide a regulated voltage. A controller is configured to provide the control signal based on a signal indicative of an operating parameter or condition of the circuit. A clock generator signal is configured to set a delay based on the control signal and provide a clock signal according to the delay. A comparator circuit is configured to provide a digital output signal based on an analog input signal, the regulated voltage, and the clock signal, and the comparator circuit includes logic configured to provide a ready signal responsive to the comparator circuit completing a compare cycle.

Another described example relates to a system that includes an analog circuit, an analog-to-digital converter (ADC) circuit, and a digital circuit. The analog circuit has an analog output. The ADC circuit has an analog input and a digital output, in which the analog input is coupled to the analog output. The ADC circuit includes a regulator circuit, a comparator circuit, and a clock generator circuit. The regulator circuit has a regulator output. The comparator circuit has a first voltage input, a clock input, a comparator output, and a signal output, in which the first voltage input is coupled to the regulator output and the comparator output is coupled to the digital output. The clock generator circuit has a second voltage input and the clock generator circuit comprising a programmable delay circuit, the programmable delay circuit having a signal input, a clock output, in which the second voltage input is coupled to the regulator output, the signal input is coupled to the signal output, the clock output is coupled to the clock input. The digital circuit has a digital input coupled to the comparator output.

### BRIEF DESCRIPTION OF THE DRAWINGS

FIG. 1 is a block diagram of an example analog-to-digital converter circuit.

FIG. 2 is a block diagram of part of an analog-to-digital converter circuit depicting an example of timing control circuitry.

FIG. 3 is a block diagram of example timing control circuitry that can be implemented in an analog-to-digital converter circuit.

FIG. 4 is a circuit diagram of an example of a low-dropout voltage regulator that can be implemented in an analog-to-digital converter circuit.

FIG. 5 is a circuit diagram of an example comparator that can be implemented in an analog-to-digital converter circuit.

FIG. 6 is a circuit diagram of example logic circuitry that can be implemented in an analog-to-digital converter circuit.

FIG. 7 is a block diagram of part of an analog-to-digital converter circuit depicting another example of timing control circuitry.

FIG. 8 is a circuit diagram of an example edge comparator that can be implemented in the circuit of FIG. 7.

FIG. 9 is a circuit diagram of an example charge pump and programmable delay circuit that can be implemented in the circuit of FIG. 7.

FIG. 10 is a diagram of an example analog front end circuit that can be implemented in the circuits of FIGS. 1, 2, and/or 7.

FIG. 11 is a signal diagram showing signals for the analog-to-digital converter that includes timing control circuitry.

FIG. 12 depicts an example of a system that includes an analog-to-digital converter with timing control circuitry.

### DETAILED DESCRIPTION

This description relates to a circuit to control timing for conversion circuitry, such as analog-to-digital converters (ADCs).

As an example, conversion circuitry, such as an ADC, includes a regulator circuit, a comparator circuit and timing control circuitry. The regulator circuit is configured to provide a regulated voltage across a decoupling capacitor to provide power to various parts of the conversion circuitry (e.g., the comparator circuit and the timing control circuitry). The timing control circuitry can include a controller and a programmable delay circuit, in which the programmable delay circuit can be part of or coupled to a clock generator. As described herein, the controller is configured to provide the control signal based on a signal indicative of one or more of an operating parameter and/or condition of the conversion circuitry. The comparator circuit also can include logic configured to provide the ready signal (e.g., a signal pulse) to indicate the comparator circuit has completed a compare cycle. The clock generator includes programmable delay circuit that is configured to set a delay based on the control signal, and the clock generator is configured to provide a clock signal based on the delay and responsive to a ready signal (e.g., a pulse provided by the comparator circuit). The comparator circuit is thus configured to provide a digital output signal (e.g., digital data) based on one or more analog input signals, the regulated voltage, and with a cycle time defined by the clock signal.

As a further example, the operating parameter and/or condition of the conversion circuitry, based on which the controller provides the control signal, can depend on the example embodiment of the timing control circuitry implemented in the conversion circuitry and application requirements. The timing control circuitry can include a programmable delay circuit configured to implement an amount of delay for the clock signal based on the control signal. In one example, the controller is configured to provide the control signal representing a delay value based on a temperature of at least a portion of the conversion circuitry and/or trim data. One or more temperature sensors can be distributed across an integrated circuit (IC) that includes the conversion circuitry, and the temperature can be based on respective temperature measurements. The trim data can be stored in memory based on testing performed at manufacture (e.g., wafer and/or package testing), and the trim data can be representative of trimming that is applied to the conversion circuitry to achieve desired performance across process corners and/or user specifications. For example, the trim data is used to modify the programable delay to ensure that the ADC clock cycles are spread throughout the conversion window. This makes the ADC conversion time fixed across process and temperature, which reduces the LDO output ripple.

In another example, the timing control circuitry includes an edge comparator circuit and a charge pump. The edge comparator circuit is configured to provide timing signal based on an end-of-conversion signal and a sample signal. For example, the conversion circuitry includes logic or other circuitry configured to provide the end-of-conversion signal representative of a number of compare cycles and the sample signal can represent a sample timing window defined for the conversion circuitry. The charge pump circuit is configured to provide a charge pump voltage based on the timing signal, and the programmable delay circuit of the clock generator can be configured to implement an amount of delay for the clock signal based on the charge pump voltage.

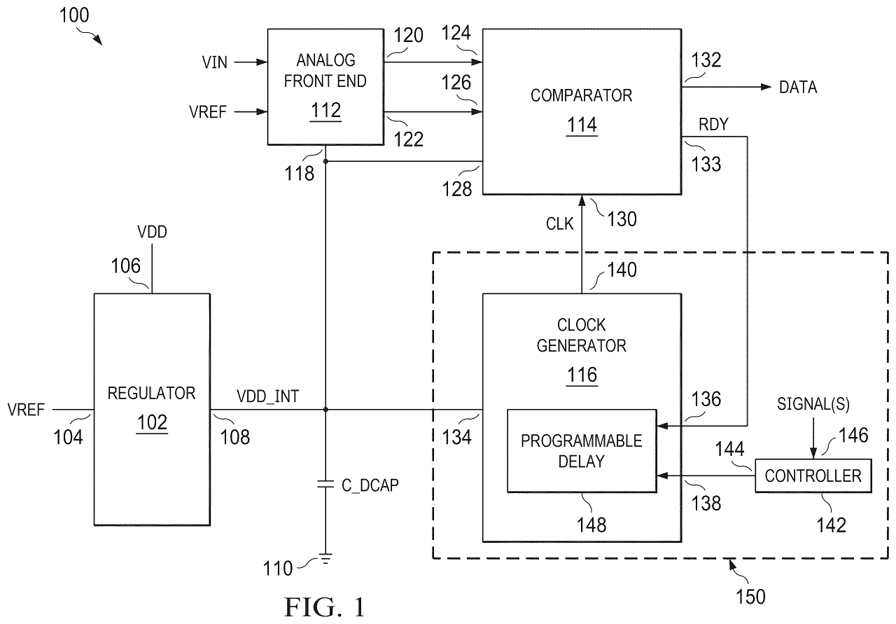

FIG. 1 is a block diagram of an example ADC circuit 100. The ADC circuit 100 can be implemented on an IC chip, and the IC chip can include multiple instances of the ADC circuit 100. As an example, the IC chip is a controller for a power converter, such as a multi-phase DC to DC power converter. One or more instances of the ADC circuit 100 can be implemented in ICs for a variety of other purposes. As described herein, the ADC circuit 100 can be fabricated on a die with reduced area compared to existing ADCs leading to a reduced area for the IC.

The ADC circuit includes a regulator circuit 102 having a reference input 104, a supply input 106, and a regulator output 108. For example, the regulator circuit 102 receives a reference voltage (VREF) at the reference input 104 and a supply voltage (VDD) at the supply input 106. A capacitor (e.g., a decoupling capacitor-C_DCAP) can be coupled between the regulator output 108 and a ground terminal 110. The regulator circuit 102 can be implemented as a low drop-out (LDO) voltage regulator or another type of circuit configured to provide a regulated voltage, shown as VDD_INT, at the regulator output 108 responsive to VREF and VDD. In an example where the ADC circuit 100 is implemented in an IC (e.g., on chip), the regulated voltage VDD_INT can be a voltage that is supplied through connections (e.g., a voltage rail) to internal components of the ADC circuit within the IC, including an analog front end circuit 112, a comparator circuit 114, and a clock generator circuit 116.

The analog front end circuit 112 includes a voltage input 118 and first and second front-end outputs 120 and 122, in which the voltage input 118 is coupled to the regulator output 108. The first and second front-end outputs 120 and 122 are coupled to respective inputs 124 and 126 of the comparator circuit 114. The analog front end circuit 112 is configured to provide an analog input signal as a differential input signal at first and second front-end outputs 120 and 122 based on another analog input signal VIN and the reference signal VREF. The comparator circuit 114 also includes a voltage input 128, a clock input 130, a comparator output 132, and a signal output 133. The voltage input 128 is coupled to the regulator output 108. The clock generator circuit 116 has a voltage input 134, a signal input 136, a control input 138 and a clock output 140. The voltage input 134 is coupled to the regulator output 108, the signal input 136 is coupled to the signal output 133 of the comparator circuit 114, and the clock output 140 is coupled to the clock input 130 of the comparator circuit 114. The ADC circuit 100 also includes a controller 142 having a control output 144 coupled to the control input 138 of the clock generator circuit 116. The controller 142 (e.g., a microcontroller or field programmable gate array (FPGA), an embedded processing unit or the like) can also include one or more inputs 146. The controller 142 is configured to provide the control signal to control the clock generator circuit 116 based on one or more signal received at the input(s) 146. The one or more signal inputs 146 can receive one or more respective signals indicative of an operating parameter and/or condition of the ADC circuit 100.

As an example, the operating parameter is a temperature and the one or more signals have respective values representative of temperature measured (e.g., by one or more temperature sensors) at one or more locations distributed across the IC containing the ADC circuit 100. As an additional or alternative example, the operating parameter can define trimming applied to the IC containing the ADC circuit 100 to configure the ADC circuit, and the signal at the signal input 146 thus has a value representative of the trimming. Other examples of operating parameters can include wafer process corners (e.g., determined by wafer testing) and/or ADC operating speed (e.g., when a programmable feature). The controller 142 can be configured to provide the control signal based on the operating parameter(s) (e.g., temperature and/or ADC trimming) specified by the signals received at the one or more inputs 146. Such control based on the one or more operating parameters can be considered an open loop type of timing control for the ADC circuit 100.

As a further example, in which the one or more signals are indicative of an operating condition of the ADC circuit 100, the operating condition can define or be representative of cyclical or other events that are associated with operation of the ADC circuit 100. For example, one operating condition represents the end (or beginning) of an ADC conversion cycle and another operating condition represents the end (or beginning) of an ADC sample cycle. The controller can be configured to provide the control signal based on a comparison of the operating conditions, such as to implement a closed loop type of timing control for the ADC circuit.

The clock generator circuit 116 can include programmable delay circuit 148 having inputs coupled to the inputs 136 and 138. The clock generator circuit 116 is configured to set a delay based on the control signal at 138. The clock generator circuit 116 thus can provide a clock (CLK) signal at the clock output 140 based on the RDY signal at 136 and the delay set by the programmable delay circuit 148. For example, the CLK signal includes a pulse (e.g., a square wave with a 50% duty cycle) that oscillates between high and low states at a frequency that defines a cycle time for the comparator circuit 114. The comparator circuit 114 is configured to provide a digital output signal (DATA) at comparator output 132 based on an analog input signal, the regulated voltage, and the clock signal. As described herein, the comparator circuit 114 can include logic configured to provide a ready signal (RDY) responsive to the comparator circuit completing a compare cycle.

Timing control circuitry 150, which is defined by the controller 142 and the clock generator circuit 116, is thus configured to set the CLK signal for adjusting the cycle time of the comparator circuit 114 to reduce voltage ripple in the regulated voltage VDD_INT provided at the regulator output 108. In some examples, the controller 142 is configured to adjust the frequency of the CLK signal based on process trim and temperature information such that the end-of-conversion (EOC) rising edge is aligned with (or approximates) sampling falling edge. In other examples, the controller 142 is configured to implement closed loop control to adjust the comparator cycle time so the EOC rising edge aligns with (or approximates) the sampling falling edge. Because the timing control circuitry 150 can reduce the ripple, the ADC circuit can use a smaller internal capacitor C_DECAP than many existing approaches, which can result in an overall reduction in the area of the IC that includes the ADC circuit. The reduction in IC area can be further increased depending on the number of instances of the ADC circuit 100 implemented on the IC. For example, it is expected that a savings of approximately 15000 μm² can be achieved per instance of the ADC circuit 100 (e.g., based on reducing the C_DCAP from approximately 400 pF to approximately 200 pF). Additionally, the reduction in the C_DCAP and reduced ripple in the regulated voltage VDD_INT can increase overall ADC accuracy over existing approaches.

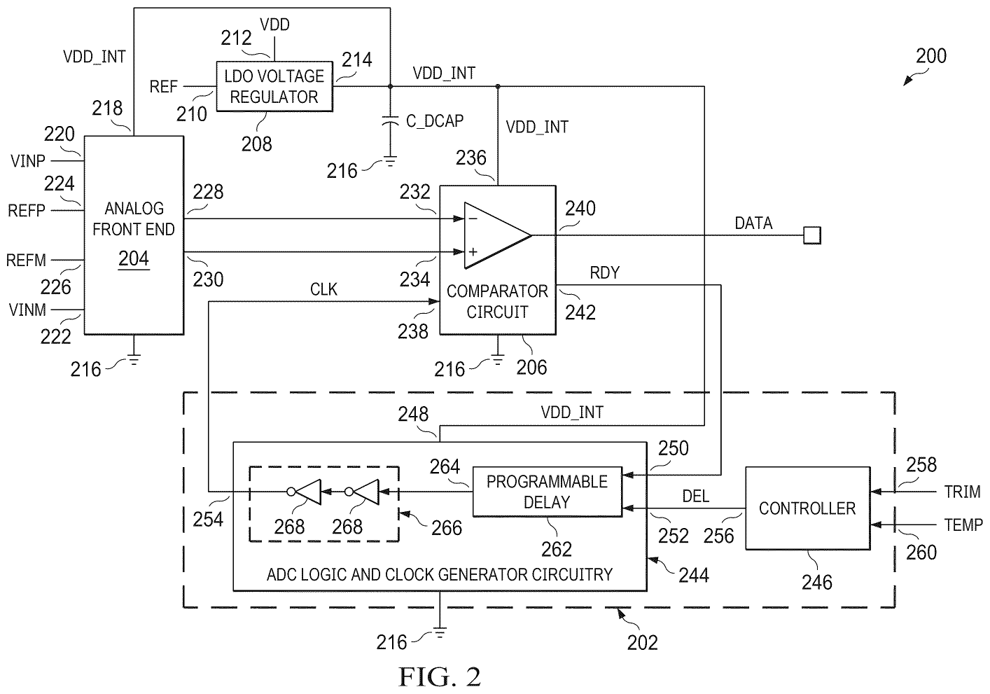

FIG. 2 is a block diagram of part of an ADC circuit 200. The ADC circuit 200 provides an example of circuitry that can be used to implement the ADC circuit 100 of FIG. 1. Accordingly, the description of FIG. 2 can refer to certain aspects of the description of FIG. 1. In the example of FIG. 2, the ADC circuit 200 includes an example timing control circuitry 202 (e.g., timing control circuitry 150), an analog front end circuit 204 (e.g., analog front end circuit 112), a comparator circuit 206 (e.g., comparator circuit 114), and an LDO voltage regulator 208 (e.g., regulator circuit 102).

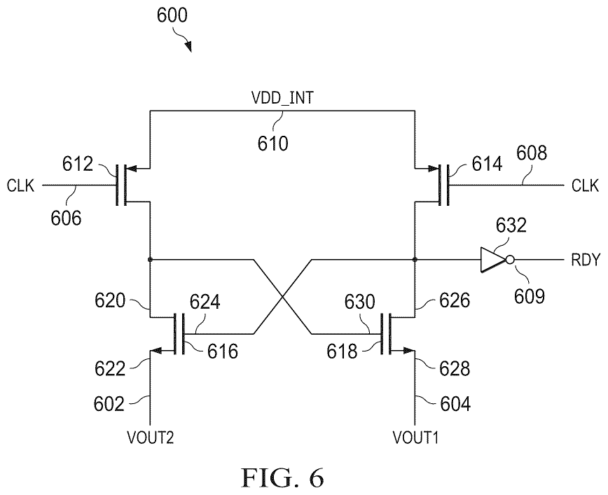

The LDO voltage regulator 208 includes a reference input 210, a supply input 212, and a regulator output 214. A capacitor C_DCAP is coupled between the regulator output 214 and a ground terminal 216 of the ADC circuit 200. The analog front end circuit 204 includes a voltage input 218, analog inputs 220, 222, reference inputs 224 and 226, and first and second analog front end (AFE) outputs 228 and 230. The voltage input 218 is coupled to the regulator output 214 to receive the regulated supply voltage VDD_INT. The analog inputs 220 and 222 can receive positive and negative input signals (e.g., constituting a differential signal), shown as VINP and VINM, respectively, and the reference inputs 224 and 226 can receive respective reference voltages REFP and REFM. The AFE outputs 228 and 230 are coupled to respective inputs 232 and 234 of the comparator circuit 206. The comparator circuit 206 also includes a voltage input 236, a clock input 238, a comparator output 240, and a ready signal output 242. The voltage input 236 is coupled to the regulator output 214. The comparator circuit 206 is configured to provide a DATA signal at the comparator output 240 based on the signals at the inputs 232 and 234 and responsive to a clock signal at the clock input 238. The DATA signal provides a digital representation of the analog input signal (VINM, VINP) received at analog inputs 220 and 222. The comparator circuit 206 can also include logic (not shown, but see, e.g., FIG. 6) configured to provide a ready (RDY) signal at the ready signal output 242 representative of a completion of a compare cycle provided by the comparator circuit 206.

The timing control circuitry 202 includes ADC logic and clock generator circuitry 244 (e.g., clock generator circuit 116) and a controller (also referred to as a delay controller) 246 (e.g., controller 142). The ADC logic and clock generator circuitry 244 includes a voltage input 248, a signal input 250, a control input 252, and a clock output 254. The voltage input 248 is coupled to the regulator output 214, the signal input 250 is coupled to the ready signal output 242, and the clock output 254 is coupled to the clock input 238 of the comparator circuit 206. The controller 246 has a control output 256 coupled to the control input 252 of the ADC logic and clock generator circuitry 244. The controller 246 also includes inputs 258 and 260 that receive respective operating parameter signals, namely, a process trim (TRIM) signal and a temperature (TEMP) signal.

In the example of FIG. 2, the ADC logic and clock generator circuitry 244 includes a programmable delay circuit 262 having inputs coupled to the signal input 250 and control input 252, respectively. The programmable delay circuit 262 also has an output 264 coupled to another delay circuit 266. For example, the delay circuit 266 includes an arrangement of inverters 268 (e.g., two or more inverters coupled in series) between the output 264 of the programmable delay circuit 262 and the clock output 254 of the ADC logic and clock generator circuitry 244. The programmable delay circuit 262 and the delay circuit 266 can thus form a clock signal path configured to provide a CLK signal based on the RDY signal and a delay control (DEL) signal.

The controller 246 (e.g., a microcontroller or FPGA) is configured to provide the delay control (DEL) signal at the control output 256 based on the TRIM and TEMP signals received at inputs 258 and 260, respectively. The TRIM and TEMP signals are representative of respective operating parameters for the ADC circuit 200. For example, the TRIM signal can be a digital value (e.g., a number of bits stored in on-chip non-volatile memory) that defines trimming of the ADC circuit 200, which can be determined by testing of the die or packaged IC containing the ADC circuit. The digital trim bits can be determined (e.g., by using a look-up table) based on the measured average internal delay in nominal operating condition and temperature. The TEMP signal can be a digital value representing a temperature at one or more locations across the IC containing the ADC circuit 200. Additionally, or alternatively, the TEMP signal can represent an aggregate (e.g., combined temperature) from multiple sensors distributed across the IC containing the ADC circuit 200, which can be a time-averaged, instantaneous, or weighted temperature. The DEL signal has a value (e.g., a digital value) representative of an amount of delay to be implemented by the programmable delay circuit 262, as determined by the controller based on the TRIM and TEMP signals. For example, the controller can be a microcontroller or FPGA that includes a lookup table configured to provide the DEL signal with a value determined according to the values of the TRIM and TEMP signals (e.g., providing indices for the lookup table). The programmable delay circuit 262 is configured to implement a variable amount of delay on the RDY signal based on the DEL signal and provide a delayed version of the RDY signal. The other delay circuit 266 can implement a known (e.g., substantially fixed) amount of delay on the delayed version of the RDY signal to provide the clock signal at the clock output 254. As described herein, the CLK signal controls the cycle time of the comparator circuit 206 and thus the rate at which bits of the DATA signal are provided at the comparator output 240.

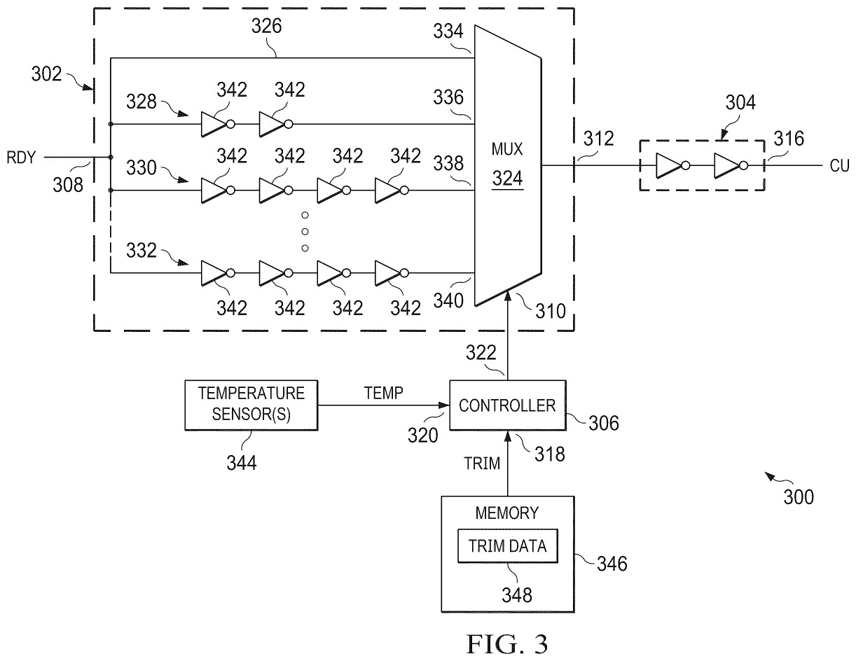

FIG. 3 is a block diagram of example timing control circuitry 300 that can be implemented in an analog-to-digital converter circuit. The timing control circuitry 300 can be used to implement the timing control circuitry 202 in the example ADC circuit 200 of FIG. 2. The timing control circuitry 300 includes a programmable delay circuit 302 (e.g., programmable delay circuit 148 or 262), a fixed delay circuit 304 (e.g., delay circuit 266), and a controller 306 (e.g., controller 142 or 246). The programmable delay circuit 302 includes a signal input 308, a control input 310, and an output 312. The fixed delay circuit 304 has an input 314 and a clock output 316, in which the input 314 is coupled to the output 312. The controller 306 has operating parameter inputs 318 and 320 and a control output 322, in which the control output 322 is coupled to the control input 310 of the programmable delay circuit 302.

In the example of FIG. 3, the programmable delay circuit 302 includes a multiplexer 324 and a plurality of delay paths 326, 328, 330, and 332 coupled between the signal input 308 and the output 312 of the programmable delay circuit 302. In the example of FIG. 3, the multiplexer has a multiplexer output that is coupled to the output 312 of the programmable delay circuit 302. While the example of FIG. 3 includes four delay paths, the programmable delay circuit 302 can have any number of two or more delay paths as indicated by the ellipsis. The multiplexer 324 includes a plurality of multiplexer inputs 334, 336, 338, and 340 and a selection input 310, in which the selection input 310 is coupled to the control output 322 of the controller 306. There can be any number of multiplexer inputs commensurate with the number of delay paths. For example, the delay path 326 includes a connection (e.g., a direct connection) between the signal input 308 and the multiplexer input 334. Each of the other delay paths 328, 330, and 332 includes a number of delay cells (e.g., shown as inverters) 342 coupled between a respective one of the multiplexer inputs and the signal input. Each of the delay paths 326, 328, 330, and 332 can be configured to provide a respective amount of delay, such as ranging from minimum delay (e.g., no delay for path 326) to a maximum time delay (e.g., path 332). The amount of delay implemented for each delay path 326, 328, 330, and 332 can be defined based on the number and/or type of delay cells implemented in each respective path.

In the example of FIG. 3, one or more temperature sensors 344 are configured to provide a temperature (TEMP) signal at the input 320. The TEMP signal can be a digital value representative of temperature measured by the temperature sensor(s) 344 at one more locations of an IC containing an ADC circuit that includes the timing control circuitry 300. In an example, multiple temperature sensors 344 can be distributed across the IC (or within the package) configured to provide temperature information for the IC that is digitized and aggregated to provide the TEMP signal. The temperature sensors 344 can be implemented on the IC for other purposes and leveraged in the ADC circuit for setting the programmable delay as described herein. In other examples, dedicated temperature sensors could be implemented on the IC for the ADC circuit.

A memory (e.g., nonvolatile memory) 346 can be configured to store trimming data 348 and provide a trimming (TRIM) signal at the input 318. The memory 346 can be implemented on the IC for other purposes and leveraged by the ADC circuit for setting the programmable delay as described herein. In other examples, the memory 346 can be part of the ADC circuit. The TRIM signal can be a digital value (e.g., process trim bits) specifying a trimming command value based on testing performed on the IC at manufacture (e.g., wafer-level and/or package-level testing). The trimming data 348 can be used to configure the ADC circuitry (e.g., the ADC circuit 100 or 200) implementing the timing control circuitry 300 to achieve desired performance across process corners and/or user specifications. The controller 306 is configured to provide a control signal based on operating parameters of the ADC circuit, as defined by the TEMP and TRIM signals. The multiplexer 324 is configured to connect one of the plurality of delay paths between the signal input 308 and the output 312 of the multiplexer to set a delay for the programmable delay circuit 302 responsive to the control signal. The timing control circuit 300 thus is configured to provide a clock CLK signal at the clock output 316 responsive to a ready (RDY) signal at the signal input 308 and based on the delay provided by the programmable delay circuit 302.

As a further example, the controller 306 in FIG. 3 is a microcontroller configured to select an amount of delay as a function of the TEMP and TRIM signals, such as shown in the algorithm shown in the following Table. The algorithm in the Table can be defined in a hardware description language that provides instructions executable by the controller to define the digital delay value (e.g., the DEL signal) for commanding the programmable delay circuit 302. For example, the algorithm shown in the Table can be described in a register-transfer level abstraction that defines the function performed by the controller 306 based on the TEMP and TRIM signals.

TABLE
If TEMP between T1 to T2, Digital_Delay<n:0> = Process_Trim + 2;
Else If TEMP between T2 to T3, Digital_Delay<n:0> = Process_Trim +1;
Else If TEMP between T3 to T4, Digital_Delay<n:0> = Process_Trim
Else If TEMP between T4 to T5, Digital_Delay<n:0> = Process_Trim −1;
Else If TEMP between T5 to T6, Digital_Delay<n:0> = Process_Trim −2.

where:
Digital Delay<n: 0> is a n-bit value corresponding to the DEL signal provided at the control output 322, where n denotes the number of bits;
TEMP represents the TEMP signal provided at the operating parameter input 320;
T1, T2, T3, T4, T5, and T6 each defines a respective different temperature threshold value; and
Process_Trim represents a trim value corresponding to the TRIM signal provided at the operating parameter input 318.

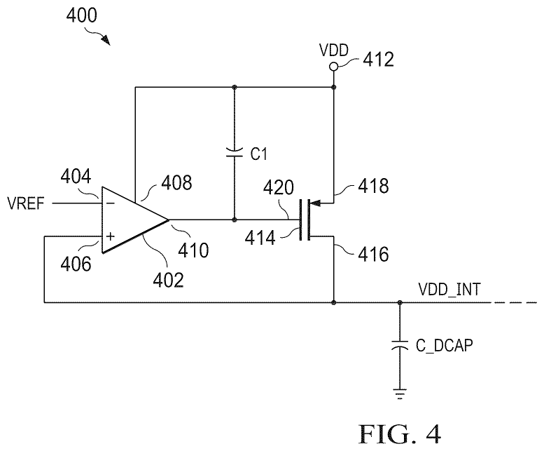

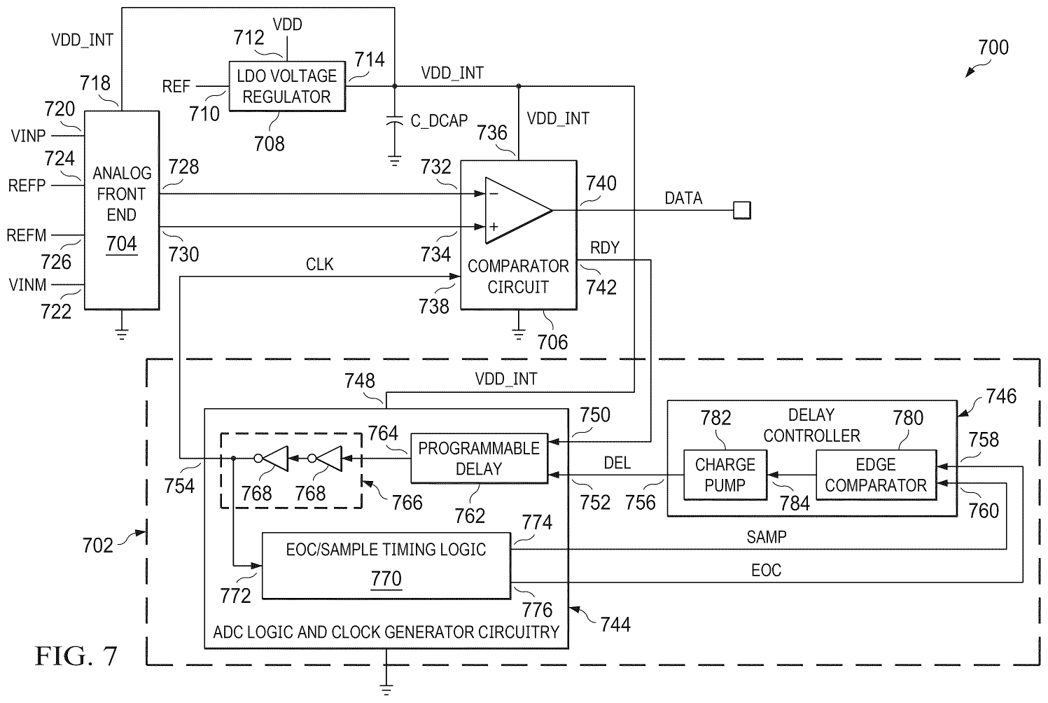

As a further example, FIG. 4 is a circuit diagram of an example of a LDO voltage regulator 400. The LDO voltage regulator 400 can be used to implement the regulator circuit 102 of FIG. 1, the LDO voltage regulator 208 of FIG. 2, or the LDO voltage regulator of FIG. 7. Other configurations of the regulator circuit can be used in other examples. The LDO voltage regulator 400 can be implemented within an IC implementing an ADC circuit and be configured to provide a regulated voltage VDD_INT, such as described herein.

In the example of FIG. 4, the LDO voltage regulator 400 includes an operational amplifier (op-amp) 402 having an inverting input 404, a non-inverting input 406, a power input 408, and an output 410. A reference voltage VREF can be applied at the inverting input 404 and the non-inverting input 406 can be coupled to a voltage terminal 412, which can be coupled to another power supply. The other power supply (not shown) can be external to the IC that includes the LDO voltage regulator 400 and be configured to provide a supply voltage VDD at the voltage terminal 412.

The LDO voltage regulator 400 includes transistor 414 having a first current input 416, a second current input 418, and a control input 420. The first current input 416 is coupled to the non-inverting input 406, the second current input 418 is coupled to the voltage terminal 412, and the control input 420 is coupled to output 410 of the op-amp 402. In an example, the transistor is a field effect transistor (FET), such as an n-channel or p-channel FET. In other examples, a different type of transistor can be used to implement the transistor 414, such as a bipolar junction transistor (BJT), insulated-gate bipolar transistor (IGBT), laterally-diffused metal-oxide semiconductor (LDMOS) transistors, or the like. A capacitor C1 can be coupled between the voltage terminal 412 and the output 410 of the op-amp 402. A decoupling capacitor C_DCAP is coupled between the non-inverting input 406 and a ground terminal. The LDO voltage regulator 400 is thus configured to provide a regulated output voltage VDD_INT across the decoupling capacitor C_DCAP responsive to VREF and the supply voltage VDD.

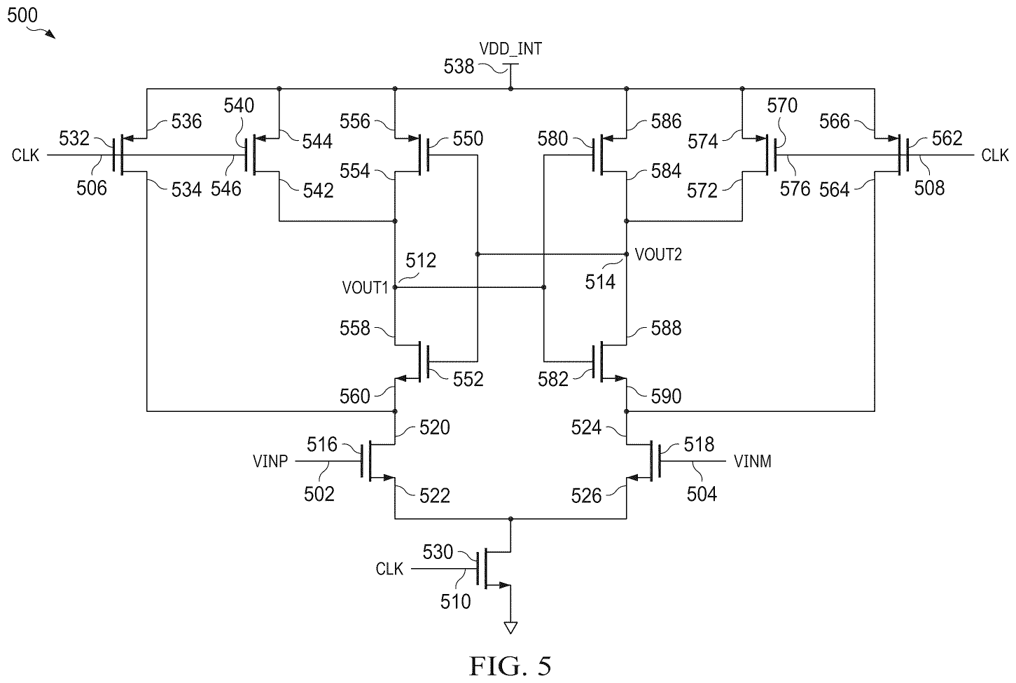

FIG. 5 is a circuit diagram of an example comparator circuit 500 that can be implemented in an analog-to-digital converter circuit. The example comparator circuit 500 can be used to implement the comparator circuit 114 of FIG. 1, the comparator circuit 206 of FIG. 2, or the comparator circuit of FIG. 7. Other configurations of the comparator circuit can be used in other examples.

In the example of FIG. 5, the comparator circuit 500 includes voltage inputs 502 and 504, clock inputs 506, 508, and 510, and comparator outputs 512 and 514. The comparator circuit 500 can be a differential comparator. For example, the comparator circuit 500 is configured to compare voltage signals VINP and VINM received at respective voltage inputs 502 and 504 (e.g., from the analog front end circuit 112, 204) and provide comparator output signals VOUT1 and VOUT2 at respective comparator outputs 512 and 514. A cycle time for each compare cycle of the comparator circuit 500 is defined by a clock signal (CLK) received at the clock inputs 506, 508, and 510.

For example, the comparator circuit 500 includes transistors (e.g., n-channel FETs) 516 and 518. The transistor 516 has a first current input (e.g., drain) 520, a second current input (e.g., a source) 522, and a control input (e.g., gate), in which the control input is coupled to the voltage input 502 to receive the input voltage signal VINP. The transistor 518 has a first current input (e.g., drain) 524, a second current input (e.g., a source) 526, and a control input (e.g., gate), in which the control input is coupled to the voltage input 504 to receive the input voltage signal VINM. Each of the second current inputs 522 and 526 are coupled together (e.g., at a common node), and a transistor (e.g., n-channel FET) 530 is coupled between the second current inputs 522 and 526 and a ground terminal. The transistor 530 has a control input coupled to the clock input 510.

The comparator circuit 500 includes a transistor (e.g., a p-channel FET) 532 having a first current input (e.g., drain) 534 and a second current input (e.g., source) 536, in which the first current input 534 is coupled to the first current input 520 of the transistor 516 and the second current input 536 is coupled to a voltage supply input 538. The voltage supply input 538 can be coupled to the output of a voltage regulator (e.g., regulator 102 or 208) to receive a regulated voltage VDD_INT. The transistor 532 also has a control input coupled to the clock input 506 to receive a CLK signal. Another transistor (e.g., p-channel FET) 540 has a first current input (e.g., drain) 542, a second current input (e.g., source) 544, and a control input (e.g., gate) 546, in which the second current input 544 is coupled to the voltage supply input 538 and the control input 546 is coupled to the clock input 506, and the first current input 542 is coupled to the comparator output 512. A pair of transistors 550 and 552 are coupled between the voltage supply input 538 and the first current input 520 of the transistor 516. The transistor 550 (e.g., a p-channel FET) has a first current input (e.g., drain) 554 coupled to the comparator output 512 and a second current input (e.g., source) 556 coupled to the voltage supply input 538. The transistor (e.g., an n-channel FET) 552 has a first current input (e.g., drain) 558 coupled to the comparator output 512 and a second current input (e.g., source) 560 coupled to the first current input 520 of the transistor 516. Each of the transistors 550 and 552 can have respective control inputs (e.g., gates) coupled together.

The comparator circuit 500 also includes a transistor (e.g., a p-channel FET) 562 having a first current input (e.g., drain) 564 and a second current input (e.g., source) 566, in which the first current input 564 is coupled to the first current input 524 of the transistor 518 and the second current input 566 is coupled to the voltage supply input 538. The transistor 562 also has a control input coupled to the clock input 508 to receive the CLK signal. Another transistor (e.g., p-channel FET) 570 has a first current input (e.g., drain) 572, a second current input (e.g., source) 574, and a control input (e.g., gate) 576, in which the first current input 572 is coupled to the comparator output 514, the second current input 574 is coupled to the voltage supply input 538, and the control input 576 is coupled to the clock input 506. A pair of transistors 580 and 582 are coupled between the voltage supply input 538 and the first current input 520 of the transistor 518. The transistor 580 (e.g., a p-channel FET) has a first current input (e.g., source) 584 coupled to the comparator output 512 and a second current input (e.g., drain) 586 coupled to the voltage supply input 538. The transistor (e.g., an n-channel FET) 582 has a first current input (e.g., drain) 588 coupled to the comparator output 514 and a second current input (e.g., source) 590 coupled to the first current input 524 of the transistor 518. Each of the transistors 580 and 582 have respective control inputs (e.g., gates) coupled together.

As an example, input voltages VINP and VINM are received at respective voltage inputs 502 and 504, which can be provided by an analog front end circuit (e.g., analog front end circuit 112, 204). The comparator circuit 500 also receives a clock signal CLK at clock inputs 506, 508, and 510. The clock signal CLK can be provided by a clock generator (e.g., clock generator circuit 116, 244 or timing control circuitry 300), such as described herein. In the example of FIG. 5, the comparator circuit 500 is shown as a strong-arm comparator in which the transistors 516 and 518 define a clocked differential pair. Other types of comparator circuits can be used in other examples. Transistors 552 and 582 and transistors 550 and 586 are cross-coupled pairs, and transistors 532, 540, 570, and 580 are configured to operate as pre-charge switches. The comparator circuit 500 is configured to provide comparator output signals VOUT1 and VOUT2 at respective comparator outputs 512 and 514 based on the relative input voltages VINP and VINM and responsive to the clock signal CLK. As described herein, each of the comparator output signals VOUT1 and VOUT2 can define output data having a binary value that can vary (e.g., approximating VDD_INT or ground) based on the input voltages VINP and VINM with each cycle of the clock signal CLK. In some examples, one of the comparator output signals VOUT1 and VOUT2 is used as the data output of the ADC circuit and the other signal can be disregarded (or discarded).

FIG. 6 is a circuit diagram of example logic circuitry 600, which can be implemented in an ADC circuit (e.g., ADC circuit 100, 200, 700) to provide an RDY signal. The logic circuitry 600 has signal inputs 602 and 604, clock inputs 606 and 608, and an output 609. The signal inputs 602 and 604 receive comparator output signals VOUT 2 and VOUT1, respectively (e.g., provided by the comparator circuit 500 at comparator outputs 514 and 512). Each of the clock inputs 606 and 608 can receive a CLK signal (e.g., provided by clock generator circuit 116, 244 or timing control circuitry 300). The logic circuitry 600 can also have a voltage input 610 to receive a regulated voltage VDD_INT (e.g., provided by regulator circuit 102, or voltage regulator 208, 400).

In the example of FIG. 6, the logic circuitry 600 includes switches (e.g., transistors, such as p-channel FETs) 612 and 614 coupled between the voltage input 610 and outputs of a cross-coupled pair of transistors 616 and 618. For example, the transistor 616 (e.g., an n-channel FET) has a first current input (e.g., drain) 620, a second current input (e.g., source) 622, and a control input (e.g., gate) 624. The transistor 618 (e.g., an n-channel FET) has a first current input (e.g., drain) 626, a second current input (e.g., source) 628, and a control input (e.g., gate) 630. The first current input 620 of the transistor 616 is coupled to the drain of the transistor 612 and the control input 630 of the transistor 618. The second current input 622 is coupled to the input 602 and thus receives the VOUT2 signal. The first current input 626 of the transistor 618 is coupled to the drain of the transistor 614 and the control input 624 of the transistor 616. The second current input 628 is coupled to the input 604 and thus receives the VOUT1 signal. An inverter 632 can be coupled between the output 609 and the first current input 626 of the transistor 618. As described herein, the logic circuitry 600 can be configured to provide the RDY signal as a pulsed signal that is indicative of a completion of a compare cycle implemented by an ADC comparator (e.g., comparator circuit 114, 206, 500, 706) based on the VOUT1 and VOUT2 signals and the CLK signal.

FIG. 7 is a block diagram of part of an analog-to-digital converter circuit 700 depicting another example of timing control circuitry. The ADC circuit 700 provides an example of circuitry that can be used to implement the ADC circuit 100 of FIG. 1. Accordingly, the description of FIG. 7 can refer to certain aspects of the description of FIG. 1. In the example of FIG. 7, the ADC circuit 700 includes an example timing control circuitry 702 (e.g., timing control circuitry 150), an analog front end 704 (e.g., analog front end circuit 112), a comparator circuit 706 (e.g., comparator circuit 114), and an LDO voltage regulator 708 (e.g., regulator circuit 102). The analog front end 704, the comparator circuit 706, and the LDO voltage regulator 708 can be the same as respective circuitry (e.g., analog front end circuit 204, comparator circuit 206, LDO voltage regulator 208) described with respect to FIG. 2.

Briefly stated, the LDO voltage regulator 708 includes a reference input 710, a supply input 712, and a regulator output 714. A capacitor C_DCAP is coupled between the regulator output 714 and a ground terminal. The analog front end circuit 704 includes a voltage input 718, analog inputs 720, 722, reference inputs 724 and 726, and first and second front-end outputs 728 and 730. The voltage input 718 is coupled to the regulator output 714 and the analog inputs 720 and 722 can receive positive and negative input signals VINP and VINM, respectively, and the reference inputs 724 and 726 can receive respective reference voltages REFP and REFM. The first and second front-end outputs 728 and 730 are coupled to respective inputs 732 and 734 of the comparator circuit 706. The comparator circuit 706 also includes a voltage input 736, a clock input 738, a comparator output 740, and a ready signal output 742. The voltage input 736 is coupled to the regulator output 714. The comparator circuit 706 is configured to provide a DATA signal at the comparator output 740 based on the signals at the inputs 732 and 734 and responsive to the CLK signal at the clock input 738. The comparator circuit 706 can also include logic (e.g., logic circuitry 600) configured to provide the RDY signal at the ready signal output 742 representative of a completion of a compare cycle by the comparator circuit.

The timing control circuitry 702 includes ADC logic and clock generator circuitry 744 and a delay control circuit (also referred to as a controller) 746. The ADC logic and clock generator circuitry 744 includes a voltage input 748, a signal input 750, a control input 752, and a clock output 754. The voltage input 748 is coupled to the regulator output 714, the signal input 750 is coupled to the ready signal output 742, and the clock output 754 is coupled to the clock input 738 of the comparator circuit 706. The delay control circuit 746 has a control output 756 coupled to the control input 752 of the ADC logic and clock generator circuitry 744. The delay control circuit 746 also includes inputs 758 and 760 coupled to respective logic outputs 776 and 774 of the EOC/sample timing logic 776.

In the example of FIG. 7, the ADC logic and clock generator circuitry 744 includes a programmable delay circuit 762 having inputs coupled to the signal input 750 and control input 752, respectively. The delay circuit 762 also has an output 764 coupled to another delay circuit 766. As described herein, the delay circuit 762 is configured to provide an adjustable (e.g., variable or programmable) delay based on a DEL signal. For example, the delay circuit 766 includes an arrangement of inverters 768 (e.g., two or more inverters coupled in series) between the output 764 of the delay circuit 762 and the clock output 754 of the ADC logic and clock generator circuitry 744. The programmable delay circuit 762 and the delay circuit 766 can thus form a clock signal path configured to provide a CLK signal based on the RDY signal and a delay control signal from the delay control circuit 746. In other examples, the delay circuit 766 can be omitted from the ADC logic and clock generator circuitry 744 or be implemented as part of the programmable delay circuit 762.

The ADC logic and clock generator circuitry 744 also includes EOC/sample timing logic 770. The EOC/sample timing logic 770 has an input 772 and outputs 774 and 776, in which the input 772 is coupled to the clock output 754 and the outputs 774 and 776 are coupled to the inputs 758 and 760, respectively, of the delay control circuit 746. The delay control circuit 746 includes an edge comparator circuit 780 and a charge pump circuit 782. The edge comparator circuit 780 has inputs coupled to the inputs 758 and 760 and thus are also coupled to the respective outputs 774 and 776 of the EOC/sample timing logic 770. The edge comparator circuit 780 has one or more outputs 784 coupled to a pump input of the charge pump circuit 782, and a pump output of the charge pump circuit 782 is coupled to the control output 756 of the delay control circuit 746.

In the example of FIG. 7, the EOC/sample timing logic 770 is configured to provide a sample (SAMP) signal and an EOC signal at respective outputs 774 and 776. In an example, the SAMP signal can be provided as an input to the ADC circuit 700 to specify a sampling cycle time for the ADC circuit 700 and can be passed to the output 774 by the EOC/sample timing logic 770. In another example, the EOC/sample timing logic 770 can generate the SAMP signal responsive to internal timing signals of the ADC circuit 700. The EOC/sample timing logic 770 can also include logic (e.g., a digital counter) configured to provide the EOC signal responsive to counting a number of pulses of the CLK signal. For example, the EOC/sample timing logic 770 is configured to provide the EOC signal based on a number of pulses of the clock signal relative to a count value. The edge comparator circuit 780 is configured to compare the SAMP and EOC signals and provide a comparator signal the output 784 based on the comparison of such signals. In an example, the edge comparator circuit 780 is configured to compare the falling edge of the SAMP signal with the rising edge of the EOC and provide the comparator signal at the output 784 representative of the temporal alignment between the SAMP and EOC signals. The charge pump circuit 782 is configured to provide a charge pump voltage at the control output 756 based on the comparator signal. The programmable delay circuit is configured to set an amount of delay in the clock signal path between the signal input 750 and the clock output 754. For example, the delay control circuit 746 is configured to implement closed loop control to set the delay for the programmable delay circuit 762 by aligning respective edges of the SAMP and EOC signals. The frequency of the CLK signal is thus adjusted to control the cycle time of the comparator circuit 706 so ripple in the regulated voltage VDD_INT can be reduced compared to existing approaches that rely on a larger C_DCAP. The reduced ripple in the regulated voltage VDD_INT further enables a smaller C_DCAP compared to existing approaches, which can reduce the overall footprint size of an IC die implementing the ADC circuit 700.

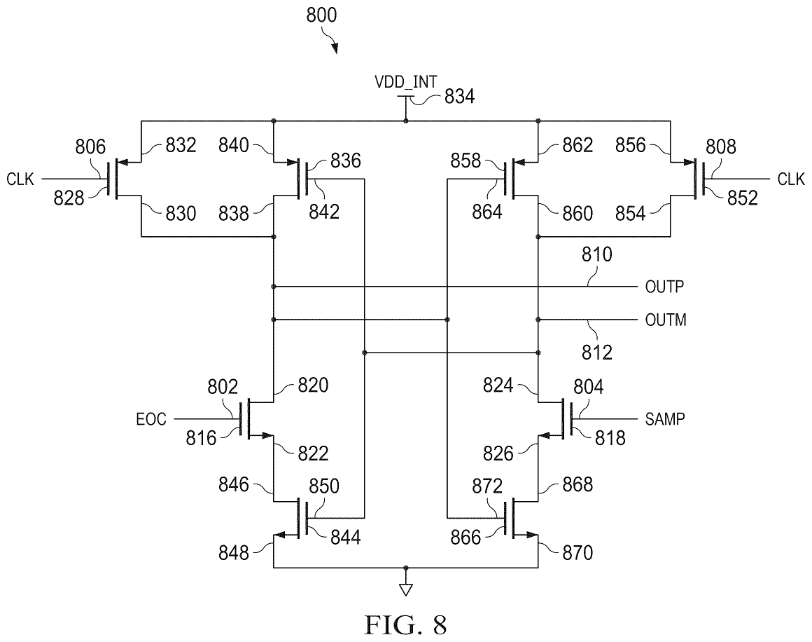

FIG. 8 depicts an example edge comparator circuit 800, which can be used to implement the edge comparator circuit 780 of FIG. 7. The edge comparator circuit 800 includes comparator inputs 802 and 804, clock inputs 806 and 808, and comparator outputs 810 and 812. The edge comparator circuit 800 includes transistors (e.g., n-channel FETs) 816 and 818. The transistor 816 has a first current input (e.g., drain) 820, a second current input (e.g., a source) 822, and a control input (e.g., gate), in which the control input is coupled to the comparator input 802 to receive the EOC signal (e.g., provided by the EOC/sample timing logic 770). The transistor 818 has a first current input (e.g., drain) 824, a second current input (e.g., a source) 826, and a control input (e.g., gate), in which the control input is coupled to the comparator input 804 to receive the SAMP signal (e.g., provided by the EOC/sample timing logic 770).

The edge comparator circuit 800 also includes a transistor (e.g., p-channel FET) 828 having a first current input (e.g., drain) 830, a second current input (e.g., source) 832, and a control input (e.g., gate). The second current input 832 is coupled to a voltage supply input 834 (e.g., providing regulated voltage VDD_INT), the control input is coupled to the clock input 806, and the first current input 830 is coupled to the comparator output 810. Another transistor 836 is coupled between the voltage supply input 834 and the first current input 820 of the transistor 816. The transistor 836 (e.g., a p-channel FET) has a first current input (e.g., drain) 838, a second current input (e.g., source) 840, and a control input (e.g., gate) 842, in which the first current input 838 is coupled to the comparator output 810 and the second current input 840 is coupled to the voltage supply input 834. Another transistor (e.g., an n-channel FET) 844, which is coupled between the transistor 816 and a ground terminal, has a first current input (e.g., drain) 846, a second current input (e.g., source) 848, and a control input (e.g., gate) 850. The first current input 846 is coupled to the second current input 822 of the transistor 816 and the second current input 848 is coupled to the ground terminal. The control inputs 842 and 850 of the respective transistors 836 and 844 are coupled together and to the comparator output 812.

The edge comparator circuit 800 also includes a transistor (e.g., p-channel FET) 852 having a first current input (e.g., drain) 854, a second current input (e.g., source) 856, and a control input (e.g., gate). The second current input 856 is coupled to the voltage supply input 834, the first current input 830 is coupled to the comparator output 812, and the control input of the transistor 852 is coupled to the clock input 808. Another transistor 858 is coupled between the voltage supply input 834 and the first current input 824 of the transistor 818. The transistor 858 (e.g., a p-channel FET) has a first current input (e.g., drain) 860, a second current input (e.g., source) 862, and a control input (e.g., gate) 864, in which the first current input 860 is coupled to the comparator output 812 and the second current input 862 is coupled to the voltage supply input 834. Another transistor (e.g., an n-channel FET) 866 is coupled between the transistor 818 and the ground terminal. The transistor 866 has a first current input (e.g., drain) 868, a second current input (e.g., source) 870, and a control input (e.g., gate) 872. The first current input 868 is coupled to the second current input 826 of the transistor 818 and the second current input 870 is coupled to the ground terminal. The control inputs 864 and 872 of the respective transistors 858 and 866 are coupled together and to the comparator output 810. By this configuration, the edge comparator circuit 800 is configured to provide output signals, shown as OUTP and OUTM, at the respective comparator outputs 810 and 812 (e.g., corresponding to the output 784 in FIG. 7) having voltage at (or approximating) one of VDD_INT or ground based on the EOC or SAMP signals received every clock cycle responsive to the CLK signal. OUTP and OUTM can be logic signal having opposite polarity (e.g., logic high or logic low). For example, when the edge comparator circuit 800 provides OUTP at VDD_INT, OUTM is at the ground voltage and when the edge comparator circuit 800 provides OUTP at the ground voltage, OUTM is at VDD_INT.

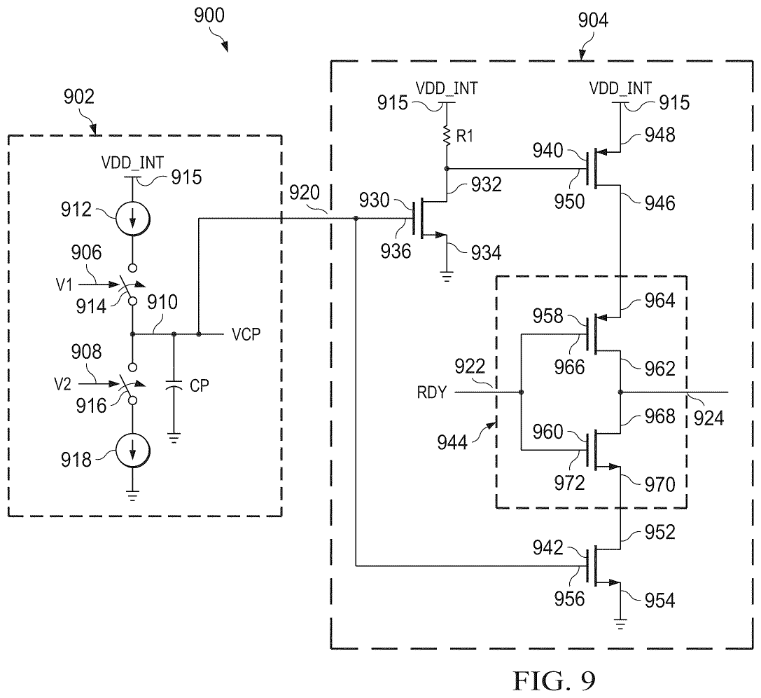

FIG. 9 is a circuit 900 depicting an example of a charge pump circuit 902 and a delay circuit 904 (e.g., which can be implemented as the charge pump 782 and the delay circuit 762 respectively, in the ADC circuit 700 of FIG. 7). The charge pump circuit 902 includes pump inputs 906 and 908 and a pump output 910. In the example of FIG. 9, the charge pump circuit 902 includes a first current source 912, and a first switch 914 coupled between a voltage supply terminal 915 (e.g., VDD_INT provided by voltage regulator 102, 400, 708) and the pump output 910. A second switch 916 and a second current source 918 are coupled between the pump output 910 and a ground terminal. A capacitor CP is coupled between the pump output 910 and the ground terminal. The charge pump is configured to control a charge pump voltage VCP across the capacitor CP, which defines a delay control signal, based on the input signals provided at the pump inputs 906 and 908. For example, the pump input 906 receives a first voltage control signal V1 and the pump input 908 receives a second voltage control signal V2 from the edge comparator (e.g., the edge comparator circuit 800). V1 and V2 can be derived (e.g., by logic) based on the signals OUTM and OUTP. Thus, one of the first or second switches is open and the other switch is closed responsive to the first and second voltage control signals V1 and V2. In examples when the EOC edge precedes the SAMP edge, the pull down switch 916 is turned on (e.g., closed) responsive to V2, the pull-up switch 914 is turned off (e.g., open), and the capacitor is discharged. In examples when the SAMP edge precedes the EOC edge, the switch 914 is turned on (e.g., closed) responsive to the V1, the second switch 916 is turned off (e.g., open), and the charge pump circuit 902 is configured to supply (e.g., source) current to charge the capacitor CP and increase VCP at the pump output 910.

The delay circuit 904 includes a control input 920 coupled to the pump output 910 of the charge pump circuit 902. The delay circuit also includes a signal input 922 and an output 924. The signal input 922 can be coupled to a ready output of a comparator circuit (e.g., the signal output 133 of comparator circuit 114, the output 609 of logic circuitry 600, the ready signal output 742 of comparator circuit 706) to receive a RDY signal.

In the example of FIG. 9, the delay circuit 904 includes a transistor (e.g., an n-channel FET) 930 having a first current input (e.g., drain) 932, a second current input (e.g., source) 934, and a control input (e.g., gate) 936, in which the control input 936 is coupled to the pump output 910 of the charge pump circuit 902. The first current input 932 can be coupled to the voltage supply terminal 915 through a resistor R1 and the second current input 934 can be coupled to the ground terminal.

The delay circuit 904 also includes a first variable resistance, shown as a transistor 940, a second variable resistance, shown as a transistor 942, and an inverter circuit 944 coupled between the voltage supply terminal 915 and the ground terminal. For example, the transistor 940 (e.g., p-channel FET) has a first current input (e.g., source) 946, a second current input (e.g., drain) 948, and a control input (e.g., gate) 950, in which the control input is coupled to the first current input 932 of the transistor 930 and the second current input 948 is coupled to the voltage supply terminal 915. The transistor 942 (e.g., n-channel FET) has a first current input (e.g., source) 952, a second current input (e.g., drain) 954, and a control input (e.g., gate) 956, in which the control input 956 is coupled to the control input 920 of the delay circuit 904 and the second current input 954 is coupled to the ground terminal.

The inverter circuit 944 includes transistors 958 and 960 coupled between the transistors 940 and 942. The transistor 958 (e.g., a p-channel FET) has a first current input (e.g., source) 962, a second current input (e.g., drain) 964, and a control input (e.g., gate) 966, in which the first current input is coupled to the output 924 and the second current input is coupled to the first current input 946 of the transistor 940. The transistor 960 (e.g., an n-channel FET) has a first current input (e.g., source) 968, a second current input (e.g., drain) 970, and a control input (e.g., gate) 972, in which the first current input 968 is coupled to the output 924 and the second current input is coupled to the first current input 952 of the transistor 942. The control inputs 966 and 972 are coupled to each other and to the signal input 922 of the delay circuit 904.

In the example of FIG. 9, the charge pump circuit is configured to control the voltage VCP across CP based on the signals OUTP and OUTM received at the pump inputs 906 and 908 (e.g., provided by the edge comparator circuit 800 based on the SAMP and EOC signals). The output voltage VCP of the charge pump circuit 902 controls the resistance of each of the transistors 940 and 942. The inverter 944 of the delay circuit 904 is thus configured to set the delay based on the resistance of each of the transistors 940 and 942 and provide a delayed version of the RDY signal at the output 924 responsive to the RDY signal. The output 924 can be coupled to a clock output (e.g., clock output 140 of FIG. 1, clock output 754 of FIG. 7) to provide a delayed version of the RDY signal based on VCP at the pump output 910 and the RDY signal at the signal input 922. The delayed version of the RDY signal at the output 924 can be provided as the CLK signal or the delayed version of the RDY signal can be provided to another the delay circuit (e.g., the delay circuit 766 that includes inverters 768), such as shown in the example of FIG. 7. The inverter 944 thus provides a propagation delay between the signal input 922 and the clock output (e.g., 140, 754) based on the charge pump voltage VCP at the control input 920.

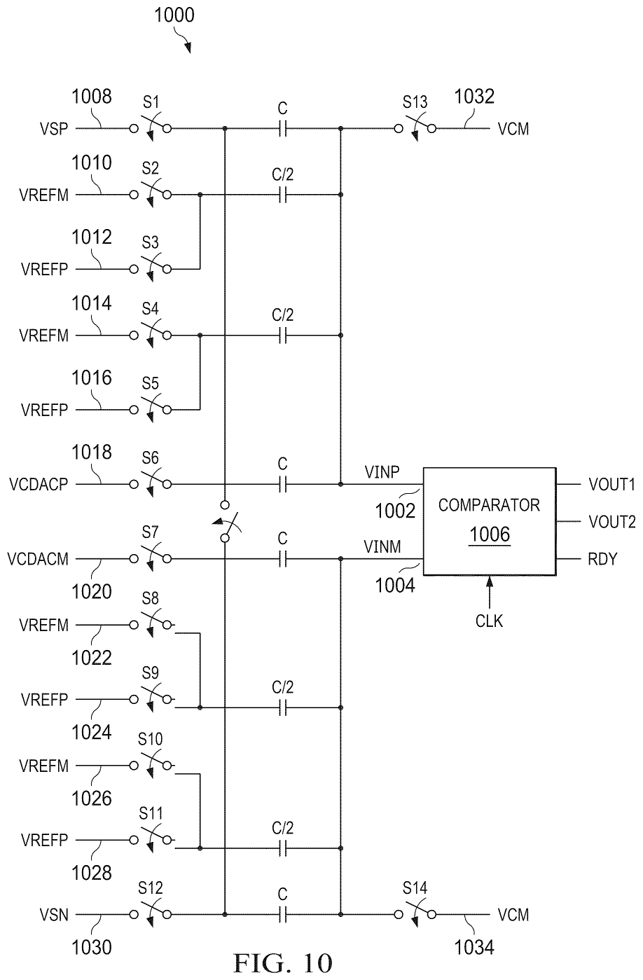

FIG. 10 is a diagram of an example analog front end circuit 1000 having outputs 1002 and 1004 coupled to respective inputs of a comparator circuit 1006. The analog front end circuit 1000 can be implemented as any of the analog front end circuits 112, 204, 704, and the comparator circuit 1006 can be implemented as any of the comparator circuits 114, 206, 500, 706. The analog front end 1000 has a plurality of inputs 1008, 1010, 1012, 1014, 1016, 1018, 1020, 1022, 1024, 1026, 1028, 1030, 1032, and 1034. Each of the inputs is coupled to a plate of a capacitor through a respective switch S1 to S14. For example, the switch S13 is coupled between the input 1032 and the top plate of a first set of capacitors and the switch S14 is coupled between the input 1034 and the top plate of a second set of capacitors, in which each of the capacitors has capacitances C or C/2, as shown, where C represents the capacitance of a DAC. Each of the inputs 1032 and 1034 can receive a common mode voltage VCM. Each of the other switches S1 through S12 is coupled between the bottom plate of the respective capacitors and respective inputs 1008 to 1030.

The analog front end 1000 is configured to implement sample and convert functions and provide analog signals VINP and VINM at respective outputs 1002 and 1004 based on controls signals (e.g., provided by ADC logic and clock generation circuitry 244, 744 according to an ADC operating algorithm) and input signals received at the respective inputs 1008 to 1034. The comparator circuit 1006 is configured to provide comparator output signals VOUT1 and VOUT2 and a RDY signal at respective comparator outputs based on the VINP and VINM signals and the CLK signal. In the example of FIG. 10, the switches S6 and S7 represent the multiple CDAC switches and the CDAC is represented as a single capacitor C. In other examples, the CDAC can be implemented by a sequence of binary weighted capacitors (adding up to C), where each capacitor will have an independent switch which is controlled based on the ADC algorithm.

As a further example, the control logic (e.g., ADC logic and clock generation circuitry 244, 744) can be configured to switch the top plate switch to VCM buffer for high bandwidth sampling with low current. Input voltages VSP, VSN bottom plate can be applied to short in convert phase for pseudo differential to differential conversion. Additionally, the VREFP/VREFM signals at the bottom plate of the respective capacitors can be driven during conversion instead of bottom plate short.

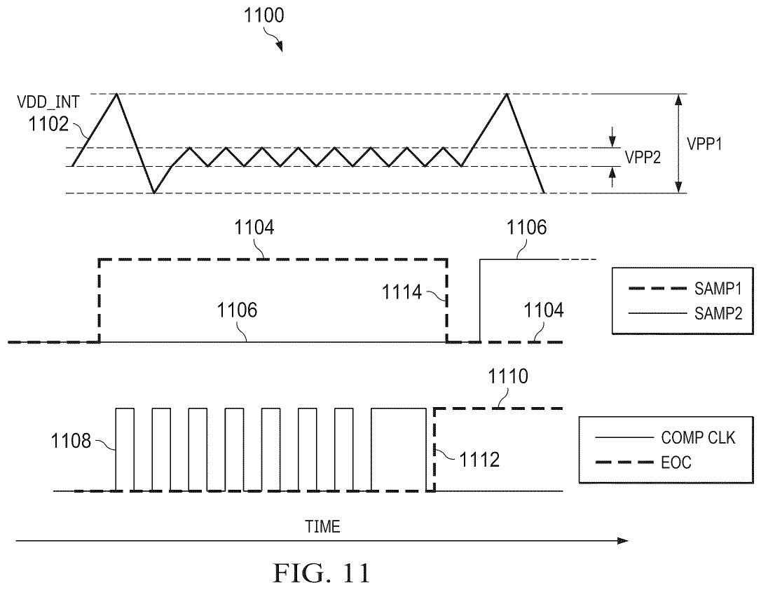

FIG. 11 is a signal diagram 1100 showing a regulated voltage signal VDD_INT (e.g., VDD_INT at 108, 214, 416, 714) 1102, sample signals 1104 and 1106, a CLK signal 1108 (e.g., CLK at 140, 254, 754), and an EOC signal 1110 (e.g., EOC at 776) for an ADC circuit described herein (e.g., ADC circuit 100, 200, 700). The signals 1102 to 1110 demonstrate the signals for the same circuit locations as shown in FIG. 11, but for the ADC circuit that includes timing control circuitry that includes a programmable delay circuit configured to delay the CLK signal each cycle so the rising edge 1111 of the EOC signal 1110 coincides with (or approximates) the falling edge 1114 of the of SAMP signal 1104. As described herein, the delay for the CLK signal can be set using an open loop approach (see, e.g., FIGS. 2-3) or a closed loop approach (see, e.g., FIGS. 7-9). As a result of delaying the CLK signal 1108, which defines the comparator cycle time, the number of comparator cycles (e.g., defined by the number of bits being converted in a conversion time window) can be distributed more evenly across the sample/conversion time period defined by the sample signal 1104. The increased duration of the CLK signal pulses during a conversion time window further enables the regulated voltage VDD_INT to recover and reduce the amount of voltage ripple VPP2 that occurs during the conversion time window compared to existing approaches. The reduced voltage ripple further enables the size of the decoupling capacitor C_DCAP to be reduced, which can enable a reduction in the overall size of the IC implementing the ADC circuit or multiple instances thereof. Moreover, because the voltage regulator does not need to drive as large of capacitor C_DCAP, the design of the voltage regulator can be further simplified, which reduces the area of the ADC circuit on the IC even more.

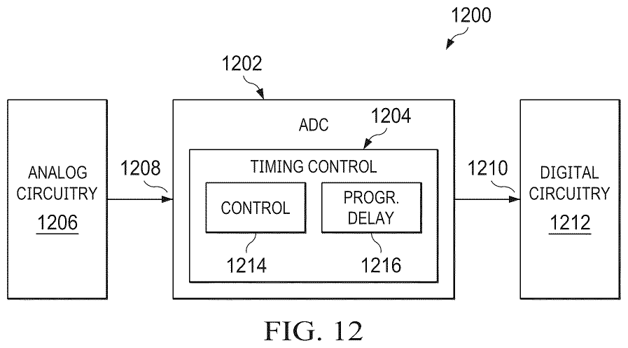

FIG. 12 depicts an example of a system 1200 that includes an ADC circuit 1202 with timing control circuitry 1204 (e.g., timing control circuitry 150, 202, 300, 702). The system can be implemented in a variety of applications, including automotive and signal processing applications, in which input analog signals are converted to respective digital signals. The system 1200 includes analog circuitry 1206 that provides an analog signal(s) to an input(s) 1208 of the ADC circuit 1202. The ADC circuit 1202 can be implemented by the ADC circuit 100, 200, or 700 described herein that is configured to convert the analog signal(s) to a respective digital output signal at an output 1210 of the ADC circuit 1202. The digital output signal at the output 1210 of the ADC circuit 1202 can be a data signal having a number of one or more bits according to the configuration of the ADC circuit 1202, which is provided to digital circuitry 1212 for processing. As described herein, the timing control circuitry 1204 includes a controller 1214 (e.g., controller 142, 246, 306, 746) and a programmable delay circuit 1216 (e.g., 148, 262, 302, 762) that are configured to set the duration (period) of the clock signal based on one or more of an operating parameter (e.g., temperature) and/or condition (e.g., alignment of ECO and SAMP signals) of the ADC circuit 1202. In this way, the clock signal thus sets the cycle time for a comparator circuit (e.g., comparator circuit 114, 206, 500, 706) to reduce voltage ripple in a regulated voltage (e.g., VDD_INT) that is supplied to various components in the ADC circuit.

In this description, numerical designations “first”, “second”, etc. are not necessarily consistent with same designations in the claims herein. Additionally, the term “couple” or variants thereof may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not alter the functional relationship between device A and device B, so device B is controlled by device A via the control signal generated by device A. In this description, the term “based on” means based at least in part on.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means within +/−10 percent of the stated value, or, if the value is zero, a reasonable range of values around zero. Modifications are possible in the described embodiments, and other embodiments are possible, within the scope of the claims.

What is claimed is:

1. A circuit comprising:
a regulator circuit having a regulator output;
a comparator circuit having a first voltage input, a clock input, and a signal output, in which the first voltage input is coupled to the regulator output;
a clock generator circuit having a second voltage input and the clock generator circuit comprising a programmable delay circuit, the programmable delay circuit having a signal input, a control input, and a clock output, in which the second voltage input is coupled to the regulator output, the signal input is coupled to the signal output, the clock output is coupled to the clock input; and
a controller having a control output coupled to the control input.

2. The circuit of claim 1, wherein the comparator circuit has a first comparator input, a second comparator input, the circuit further comprising an analog-to-digital converter front end circuit having a fourth voltage input, a first front-end output and a second front-end output, in which the fourth voltage input is coupled to the regulator output, the first front-end output is coupled to the first comparator input and the second front-end output is coupled to the second comparator input.

3. The circuit of claim 1, wherein the programmable delay circuit comprises:
a multiplexer having a plurality of multiplexer inputs and a selection input, in which the selection input is coupled to the control input; and
a plurality of delay cells, each of the delay cells coupled between a respective one of the multiplexer inputs and the signal input.

4. The circuit of claim 3, wherein the controller is configured to provide a control signal at the control output based on an operating parameter of the circuit, and
the multiplexer is configured to connect one of the plurality of delay cells between the signal input and a multiplexer output of the multiplexer to set a delay for the programmable delay circuit responsive to the control signal, and
the clock generator circuit is configured to provide a clock signal at the clock output based on a signal at the signal input and the delay for the programmable delay circuit.

5. The circuit of claim 4, wherein the operating parameter comprises a temperature of at least a portion of the circuit.

6. The circuit of claim 4, wherein the controller is further configured to provide the control signal at the control output based on a trim value.

7. The circuit of claim 1, wherein the controller comprises:
an edge comparator having a first comparator input, a second comparator input, a second comparator output and a third comparator output; and
a charge pump circuit having a first pump input, a second pump input, and a pump output, in which the first pump input is coupled to the second comparator output, the second pump input is coupled to the third comparator output, and the pump output is coupled to the signal input of the programmable delay circuit.

8. The circuit of claim 7, further comprising a capacitor coupled between the regulator output and a ground terminal, wherein the regulator circuit is configured to provide a regulated voltage at the regulator output across the capacitor.

9. The circuit of claim 8, wherein the capacitor is a first capacitor, the charge pump circuit comprises a second capacitor coupled between the pump output and the ground terminal,
wherein the edge comparator is configured to provide a charge pump control signal at one of the second comparator output or the third comparator output based on a comparison of an end-of-conversion signal at the first comparator input and a sample signal at the second comparator input,
wherein the charge pump circuit is configured to provide a charge pump voltage across the second capacitor based on the charge pump control signal,
wherein the programmable delay circuit comprises an inverter coupled between the signal input and the clock output,
wherein the inverter provides a propagation delay between the signal input and the clock output based on the charge pump voltage, and
the clock generator circuit is configured to provide a clock signal at the clock output based on a signal at the signal input and the propagation delay.

10. The circuit of claim 9, wherein the controller is configured to provide closed loop control to set a delay of the programmable delay circuit to align an end-of-conversion signal at the first comparator input and a sample signal at the second comparator input.

11. The circuit of claim 10, further comprising logic configured to provide the end-of-conversion signal based on a number of pulses of the clock signal relative to a count value.

12. A circuit, comprising:
a regulator circuit configured to provide a regulated voltage;
a controller configured to provide a control signal based on a signal indicative of an operating parameter or condition of the circuit;
a clock generator circuit configured to:
set a delay based on the control signal; and
provide a clock signal according to the delay; and
a comparator circuit configured to provide a digital output signal based on an analog input signal, the regulated voltage, and the clock signal, and the comparator circuit includes logic configured to provide a ready signal responsive to the comparator circuit completing a compare cycle.

13. The circuit of claim 12, further comprising an analog-to-digital converter front end circuit, which is powered by the regulated voltage and configured to provide the analog input signal as a differential input signal based on another analog input signal and a reference signal.

14. The circuit of claim 12, wherein the clock generator circuit comprises:
a plurality of delay cells, in which each delay cell of the plurality of delay cells is configured to provide a respective amount of delay; and
a multiplexer configured to select at least one of the plurality of delay cells to set the delay for the clock generator circuit based on the control signal.

15. The circuit of claim 14, wherein the operating parameter of the circuit comprises a temperature of at least a portion of the circuit.

16. The circuit of claim 14, wherein the controller is further configured to provide the control signal based on a trim value.

17. The circuit of claim 12, wherein the comparator circuit is a first comparator circuit, and the controller comprises:
an edge comparator circuit configured to provide timing signal based on an end-of-conversion signal and a sample signal; and
a charge pump circuit configured to provide a charge pump voltage based on the timing signal,
wherein the clock generator circuit is configured to set the delay for the clock signal based on the charge pump voltage.

18. The circuit of claim 12, wherein the controller is configured to provide closed loop control to set the delay for the clock generator circuit based on aligning respective edges of an end-of-conversion signal and a sample signal, and
wherein the end-of-conversion signal is based on a number of pulses of the clock signal relative to a count value.

19. A system, comprising:
an analog circuit having an analog output;
an analog-to-digital converter (ADC) circuit having an analog input and a digital output, in which the analog input is coupled to the analog output, and the ADC circuit comprises:
a regulator circuit having a regulator output;
a comparator circuit having a first voltage input, a clock input, a comparator output, and a signal output, in which the first voltage input is coupled to the regulator output and the comparator output is coupled to the digital output; and
a clock generator circuit having a second voltage input and the clock generator circuit comprising a programmable delay circuit, the programmable delay circuit having a signal input, a clock output, in which the second voltage input is coupled to the regulator output, the signal input is coupled to the signal output, the clock output is coupled to the clock input; and
a digital circuit having a digital input coupled to the comparator output.

20. The system of claim 19, wherein the ADC circuit further comprises:
a controller having a control output coupled to a control input of the clock generator circuit, in which the controller is configured to provide a control signal at the control output based on a signal indicative of an operating parameter or condition of the ADC circuit, the programmable delay circuit is configured to set a programmable delay based on the control signal, and the clock generator circuit is configured to provide a clock signal at the clock output based on the programmable delay and a ready signal representative of the comparator circuit completing a compare cycle.
